(19) United States
(12) Patent Application Publication
(10) Pub. No.: US 2023/0165158 A1
(43) Pub. Date: May 25, 2023

(54) MAGNETIC MEMORY DEVICES AND METHODS FOR INITIALIZING THE SAME

(71) Applicant: Samsung Electronics Co., Ltd., Suwon-si (KR)

(72) Inventors: Stuart Papworth Parkin, Halle (DE); See-Hun Yang, Halle (DE); Jiho Yoon, Halle (DE); Ung Hwan Pi, Hwaseong-si (KR)

(73) Assignee: Max-Planck-Gesellschaft zur Förderung der Wissenschaften e.V., München (DE)

(21) Appl. No.: 18/051,857

(22) Filed: Nov. 1, 2022

(30) Foreign Application Priority Data
Nov. 25, 2021 (KR) 10-2021-0164265

(51) Int. Cl. H01L 29/82; G11C 11/16

(52) U.S. Cl. CPC H01L 43/08; H01L 43/02; H01L 43/10; H01L 27/222; G11C 11/161

(57) ABSTRACT

A magnetic memory device includes a conductive line extending in a first direction, and a magnetic track extending in the first direction on the conductive line. The magnetic track includes a lower magnetic layer, a spacer layer and an upper magnetic layer sequentially stacked on the conductive line, and a non-magnetic pattern on the spacer layer and adjacent a side of the upper magnetic layer. The non-magnetic pattern vertically overlaps with a portion of the lower magnetic layer. The lower magnetic layer and the upper magnetic layer are antiferromagnetically coupled to each other by the spacer layer.

### CROSS-REFERENCE TO RELATED APPLICATIONS

This U.S. non-provisional patent application claims priority under 35 U.S.C. § 119 to Korean Patent Application No. 10-2021-0164265, filed on Nov. 25, 2021, in the Korean Intellectual Property Office, the entire contents of which are hereby incorporated by reference.

### BACKGROUND OF THE INVENTION

The present disclosure relates to magnetic memory devices, and more particularly, to magnetic memory devices using a movement phenomenon of a magnetic domain wall and methods for initializing the same.

High-speed and low-voltage memory devices have been demanded to realize high-speed and low-power electronic devices including memory devices. A magnetic memory device has been studied as a memory device satisfying these demands. The magnetic memory device has been spotlighted as a next-generation memory device because of its high-speed operation characteristics and/or non-volatile characteristics. In particular, a new magnetic memory device using a movement phenomenon of a magnetic domain wall of a magnetic material has been studied and developed.

### SUMMARY

Embodiments of the present disclosure may provide a magnetic memory device capable of easily injecting a magnetic domain wall into a magnetic track including a synthetic antiferromagnetic structure.

Embodiments of the present disclosure may also provide a method for initializing a magnetic memory device capable of easily injecting a magnetic domain wall into a magnetic track including a synthetic antiferromagnetic structure.

In an aspect, a magnetic memory device may include a conductive line extending in a first direction, and a magnetic track extending in the first direction on the conductive line. The magnetic track may include a lower magnetic layer, a spacer layer, and an upper magnetic layer sequentially stacked on the conductive line, and a non-magnetic pattern on the spacer layer and adjacent a side of the upper magnetic layer. The non-magnetic pattern may vertically overlap with a portion of the lower magnetic layer. The lower magnetic layer and the upper magnetic layer may be antiferromagnetically coupled to each other by the spacer layer.

In an aspect, a magnetic memory device may include a magnetic track extending in a first direction. The magnetic track may include a lower magnetic layer extending in the first direction, an upper magnetic layer extending in the first direction on the lower magnetic layer, a non-magnetic pattern on the lower magnetic layer and adjacent a side of the upper magnetic layer, and a spacer layer extending in the first direction between the lower magnetic layer and the upper magnetic layer. The non-magnetic pattern may vertically overlap with a portion of the lower magnetic layer in a second direction substantially perpendicular to the first direction. The spacer layer may extend between the non-magnetic pattern and the portion of the lower magnetic layer. The lower magnetic layer and the upper magnetic layer may be antiferromagnetically coupled to each other by the spacer layer.

In an aspect, a method for initializing a magnetic memory device may be provided. The magnetic memory device may include a conductive line extending in a first direction, and a magnetic track extending in the first direction on the conductive line. The magnetic track may include a lower magnetic layer on the conductive line, an upper magnetic layer on the lower magnetic layer, a spacer layer between the lower magnetic layer and the upper magnetic layer, and a non-magnetic pattern on the spacer layer and adjacent a side of the upper magnetic layer. The non-magnetic pattern may vertically overlap with a portion of the lower magnetic layer. The magnetic track may include a synthetic antiferromagnetic region in which the lower magnetic layer and the upper magnetic layer are antiferromagnetically coupled to each other by the spacer layer, and a ferromagnetic region including the non-magnetic pattern and the portion of the lower magnetic layer which vertically overlaps with the non-magnetic pattern. The portion of the lower magnetic layer which vertically overlaps with the non-magnetic pattern may have an initial magnetization direction. The method may include applying a first external magnetic field to the magnetic track to reverse the initial magnetization direction of the portion of the lower magnetic layer which vertically overlaps with the non-magnetic pattern in the ferromagnetic region to a first magnetization direction and to form a lower magnetic domain wall in the portion of the lower magnetic layer which vertically overlaps with the non-magnetic pattern, and applying a current to the conductive line to inject the lower magnetic domain wall into the lower magnetic layer in the synthetic antiferromagnetic region.

### BRIEF DESCRIPTION OF THE DRAWINGS

FIG. 1 is a perspective view schematically illustrating a magnetic memory device according to some embodiments of the present disclosure.

FIG. 2 is a cross-sectional view illustrating a magnetic memory device according to some embodiments of the present disclosure.

FIGS. 3A to 3C are cross-sectional views corresponding to a portion ‘A’ of FIG. 2 to illustrate a method of manufacturing a magnetic memory device according to some embodiments of the present disclosure

FIGS. 4A to 4F are cross-sectional views corresponding to the portion ‘A’ of FIG. 2 to illustrate a method for initializing a magnetic memory device according to some embodiments of the present disclosure.

FIG. 5 is a cross-sectional view illustrating a magnetic memory device according to some embodiments of the present disclosure.

### DETAILED DESCRIPTION

Example embodiments of the present disclosure will now be described more fully with reference to the accompanying drawings.

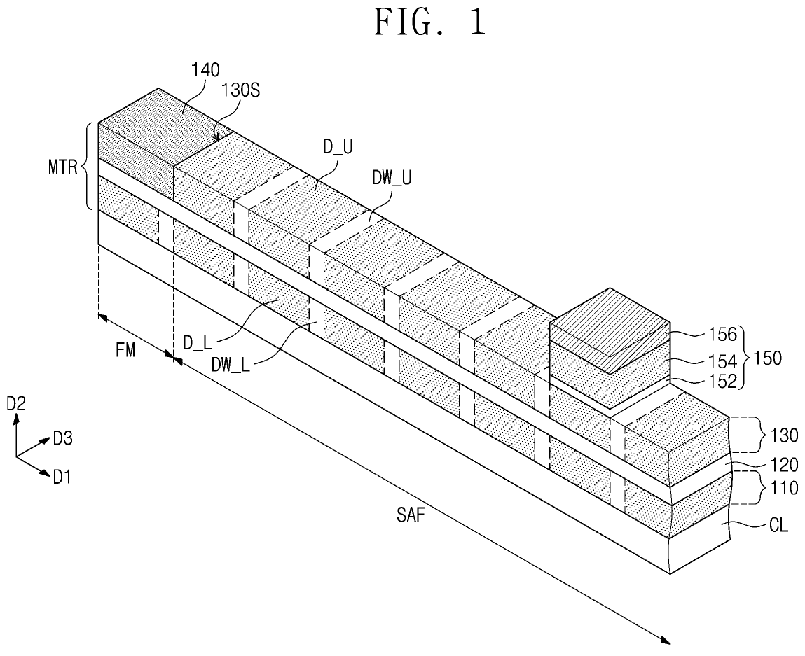

FIG. 1 is a perspective view schematically illustrating a magnetic memory device according to some embodiments of the present disclosure.

Referring to FIG. 1, a magnetic memory device may include a conductive line CL, a magnetic track MTR on the conductive line CL, and a read/write unit 150 on the magnetic track MTR. Each of the conductive line CL and the magnetic track MTR may have a line shape extending in a first direction D1. The magnetic track MTR may be stacked on the conductive line CL in a second direction D2 perpendicular to the first direction D1. Each of the conductive line CL and the magnetic track MTR may have a line shape in which a length in the first direction D1 is greater than a width in a third direction D3 perpendicular to both the first direction D1 and the second direction D2. The read/write unit 150 may be adjacent to a portion of the magnetic track MTR.

The conductive line CL may be configured to generate spin-orbit torque by a current flowing therethrough. The conductive line CL may include a material capable of generating a spin hall effect or a Rashba effect by a current flowing in the first direction D1 or an opposite direction to the first direction D1 in the conductive line CL. The conductive line CL may include a heavy metal having an atomic number of thirty (30) or more and may include, for example, iridium (Ir), ruthenium (Ru), tantalum (Ta), platinum (Pt), palladium (Pd), bismuth (Bi), titanium (Ti), or tungsten (W).

The magnetic track MTR may include a lower magnetic layer 110, a spacer layer 120 and an upper magnetic layer 130, which are sequentially stacked on the conductive line CL. The lower magnetic layer 110, the spacer layer 120 and the upper magnetic layer 130 may be stacked on the conductive line CL in the second direction D2. The lower magnetic layer 110 may be between the conductive line CL and the spacer layer 120, and the spacer layer 120 may be between the lower magnetic layer 110 and the upper magnetic layer 130. The lower magnetic layer 110, the spacer layer 120 and the upper magnetic layer 130 may have line shapes extending in the first direction D1. The conductive line CL and the magnetic track MTR may have straight line shapes extending in the first direction D1, but embodiments of the present disclosure are not limited thereto. In certain embodiments, the conductive line CL and the magnetic track MTR may have U-shaped line shapes.

The lower magnetic layer 110 may include lower magnetic domains D_L arranged in the first direction D1, and lower magnetic domain walls DW_L between the lower magnetic domains D_L. Each of the lower magnetic domains D_L may be a region in the lower magnetic layer 110, in which magnetic moments are aligned in a certain direction, and each of the lower magnetic domain walls DW_L may be a region in which directions of magnetic moments are changed between the lower magnetic domains D_L. The lower magnetic domains D_L and the lower magnetic domain walls DW_L may be alternately arranged in the first direction D1.

The upper magnetic layer 130 may include upper magnetic domains D_U arranged in the first direction D1, and upper magnetic domain walls DW_U between the upper magnetic domains D_U. Each of the upper magnetic domains D_U may be a region in the upper magnetic layer 130, in which magnetic moments are aligned in a certain direction, and each of the upper magnetic domain walls DW_U may be a region in which directions of magnetic moments are changed between the upper magnetic domains D_U. The upper magnetic domains D_U and the upper magnetic domain walls DW_U may be alternately arranged in the first direction D1. The upper magnetic domains D_U may vertically overlap with the lower magnetic domains D_L in the second direction D2, respectively. As used herein, when element A is said to “overlap” or is “overlapping” element B, it may refer to the situation where element A is said to extend over or past, and/or cover a part of, element B in a given direction. Note that element A may overlap element B in a first direction, but may or may not overlap element B in a second direction.

The lower magnetic layer 110 and the upper magnetic layer 130 may be antiferromagnetically coupled to each other by the spacer layer 120. Each of the lower magnetic layer 110 and the upper magnetic layer 130 may include a magnetic element and may include at least one of, for example, cobalt (Co), iron (Fe), or nickel (Ni). The spacer layer 120 may include a non-magnetic metal and may include, for example, ruthenium (Ru), iridium (Ir), tungsten (W), tantalum (Ta), or any alloy thereof.

The magnetic track MTR may further include a non-magnetic pattern 140 on the spacer layer 120 and adjacent a side of the upper magnetic layer 130. The non-magnetic pattern 140 may vertically overlap with a portion of the lower magnetic layer 110 in the second direction D2. For example, the non-magnetic pattern 140 may vertically overlap with a corresponding lower magnetic domain D_L of the lower magnetic domains D_L in the lower magnetic layer 110 (e.g., in the second direction D2). The non-magnetic pattern 140 may be in contact with a side surface 130S of the upper magnetic layer 130. The spacer layer 120 may be between the lower magnetic layer 110 and the upper magnetic layer 130 and may extend between the non-magnetic pattern 140 and the portion of the lower magnetic layer 110. The non-magnetic pattern 140 may include a metal oxide. The non-magnetic pattern 140 may include a same magnetic element as a magnetic element in the upper magnetic layer 130 and may further include oxygen.

The magnetic track MTR may include a synthetic antiferromagnetic region SAF and a ferromagnetic region FM. The synthetic antiferromagnetic region SAF may be a region in which the lower magnetic layer 110 and the upper magnetic layer 130 are antiferromagnetically coupled to each other by the spacer layer 120. The ferromagnetic region FM may include the non-magnetic pattern 140, and the portion (i.e., the corresponding lower magnetic domain D_L) of the lower magnetic layer 110 which vertically overlaps with the non-magnetic pattern 140. The magnetic track MTR may have a ferromagnet-synthetic antiferromagnet (FM-SAF) lateral junction structure in which the ferromagnetic region FM and the synthetic antiferromagnetic region SAF are joined to each other in the first direction D1. The ferromagnetic region FM of the magnetic track MTR may be a region used to inject a magnetic domain wall (e.g., the lower magnetic domain walls DW_L) into the synthetic antiferromagnetic region SAF of the magnetic track MTR for initialization of the magnetic memory device.

The read/write unit 150 may be on the synthetic antiferromagnetic region SAF of the magnetic track MTR. The read/write unit 150 may include a GMR sensor using a giant magneto resistance effect or a TMR sensor using a tunnel magneto resistance effect. For example, the read/write unit 150 may include a magnetic pattern 154 on the upper magnetic layer 130, a tunnel barrier pattern 152 between the upper magnetic layer 130 and the magnetic pattern 154, and an electrode pattern 156 on the magnetic pattern 154. The magnetic pattern 154 may be between the tunnel barrier pattern 152 and the electrode pattern 156. The magnetic pattern 154 may include at least one of cobalt (Co), iron (Fe), or nickel (Ni). The tunnel barrier pattern 152 may include at least one of magnesium (Mg) oxide, titanium (Ti) oxide, aluminum (Al) oxide, magnesium-zinc (Mg—Zn) oxide, or magnesium-boron (Mg—B) oxide. The electrode pattern 156 may include a conductive material and may include, for example, a metal (e.g., copper, tungsten, or aluminum) and/or a metal nitride (e.g., tantalum nitride, titanium nitride, or tungsten nitride).

The read/write unit 150 may vertically overlap with a corresponding upper magnetic domain D_U of the upper magnetic domains D_U in the upper magnetic layer 130 and a corresponding lower magnetic domain D_L of the lower magnetic domains D_L in the lower magnetic layer 110 (e.g., in the second direction D2).

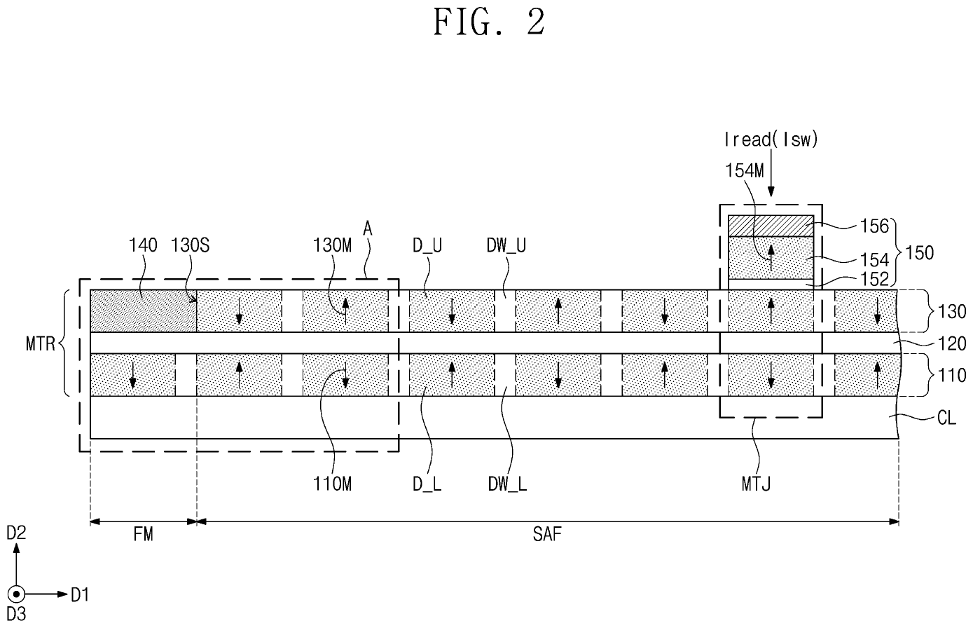

FIG. 2 is a cross-sectional view illustrating a magnetic memory device according to some embodiments of the present disclosure. Hereinafter, the descriptions to the same features as mentioned with reference to FIG. 1 will be omitted for the purpose of ease and convenience in explanation.

Referring to FIG. 2, the lower magnetic domains D_L in the lower magnetic layer 110 and the upper magnetic domains D_U in the upper magnetic layer 130 may have perpendicular magnetic anisotropy (PMA). Each of the lower magnetic domains D_L in the lower magnetic layer 110 may have a magnetization direction 110M substantially perpendicular to an interface between the lower magnetic layer 110 and the spacer layer 120, and the magnetization directions 110M of lower magnetic domains D_L directly adjacent to each other may be opposite to each other. Each of the lower magnetic domain walls DW_L may define a boundary between the adjacent lower magnetic domains D_L having the magnetization directions 110M opposite to each other. Each of the upper magnetic domains D_U in the upper magnetic layer 130 may have a magnetization direction 130M substantially perpendicular to an interface between the upper magnetic layer 130 and the spacer layer 120, and the magnetization directions 130M of upper magnetic domains D_U directly adjacent to each other may be opposite to each other. Each of the upper magnetic domain walls DW_U may define a boundary between the adjacent upper magnetic domains D_U having the magnetization directions 130M opposite to each other.

The upper magnetic domains D_U may vertically overlap with the lower magnetic domains D_L in the second direction D2, respectively, and the upper magnetic domains D_U and the lower magnetic domains D_L may be antiferromagnetically coupled to each other by the spacer layer 120. The magnetization direction 130M of each of the upper magnetic domains D_U may be antiparallel to the magnetization direction 110M of a corresponding lower magnetic domain D_L of the lower magnetic domains D_L. In the synthetic antiferromagnetic region SAF of the magnetic track MTR, the upper magnetic domains D_U and the lower magnetic domains D_L may be antiferromagnetically coupled to each other by the spacer layer 120.

The non-magnetic pattern 140 may vertically overlap with one of the lower magnetic domains D_L in the second direction D2. The corresponding lower magnetic domain D_L may have the magnetization direction 110M substantially perpendicular to the interface between the lower magnetic layer 110 and the spacer layer 120. The non-magnetic pattern 140 and the corresponding lower magnetic domain D_L may constitute the ferromagnetic region FM of the magnetic track MTR. The ferromagnetic region FM of the magnetic track MTR may be a region used to inject a magnetic domain wall (e.g., the lower magnetic domain walls DW_L) into the synthetic antiferromagnetic region SAF of the magnetic track MTR for initialization of the magnetic memory device.

When a current flows in the first direction D1 or the opposite direction to the first direction D1 in the conductive line CL, the lower magnetic domain walls DW_L in the lower magnetic layer 110 may move in the first direction D1. The movement of the lower magnetic domain walls DW_L may be due to spin-orbit torque and Dzyaloshinskii-Moriya interaction (DMI) generated at an interface between the conductive line CL and the lower magnetic layer 110. A movement direction of the lower magnetic domain walls DW_L may be dependent on chirality of the lower magnetic domain walls DW_L. Since the lower magnetic domain walls DW_L in the lower magnetic layer 110 move in the first direction D1, the upper magnetic domain walls DW_U in the upper magnetic layer 130 may also move in the first direction D1. The movement of the upper magnetic domain walls DW_U may be due to the antiferromagnetic coupling between the lower magnetic layer 110 and the upper magnetic layer 130.

The magnetic pattern 154 of the read/write unit 150 may have perpendicular magnetic anisotropy (PMA). The magnetic pattern 154 may have a magnetization direction 154M substantially perpendicular to an interface between the magnetic pattern 154 and the tunnel barrier pattern 152, and the magnetization direction 154M of the magnetic pattern 154 may be fixed in one direction. The magnetization directions 130M of the upper magnetic domains D_U in the upper magnetic layer 130 and the magnetization directions 110M of the lower magnetic domains D_L in the lower magnetic layer 110 may be changeable to be parallel or antiparallel to the magnetization direction 154M of the magnetic pattern 154.

The magnetic pattern 154 may vertically overlap with one of the upper magnetic domains D_U and a corresponding lower magnetic domain D_L of the lower magnetic domains D_L (e.g., in the second direction D2). The magnetic pattern 154, the corresponding upper magnetic domain D_U, and the corresponding lower magnetic domain D_L, which vertically overlap with each other, may constitute a magnetic tunnel junction MTJ. The magnetic pattern 154 may be a pinned layer having the magnetization direction 154M fixed in one direction, and the corresponding upper magnetic domain D_U and the corresponding lower magnetic domain D_L may be antiferromagnetically coupled to each other to constitute a free layer having a synthetic antiferromagnetic structure.

In a read operation, a read current Iread may flow through the magnetic tunnel junction MTJ. A resistance state of the magnetic tunnel junction MTJ may be detected by the read current Iread. Whether the magnetic tunnel junction MTJ is in a high-resistance state or a low-resistance state may be detected by the read current Iread. Data (0 or 1) stored in the free layer may be detected from the resistance state of the magnetic tunnel junction MTJ. In a write operation, a write current Isw may flow through the magnetic tunnel junction MTJ. A magnitude of the write current Isw may be greater than a magnitude of the read current Iread. The magnetization direction 130M of the corresponding upper magnetic domain D_U may be switched by spin transfer torque generated by the write current Isw. The magnetization direction 130M of the corresponding upper magnetic domain D_U may be switched to be parallel or antiparallel to the magnetization direction 154M of the magnetic pattern 154, by the spin transfer torque generated by the write current Isw. The magnetization direction 110M of the corresponding lower magnetic domain D_L may be switched to be antiparallel to the magnetization direction 130M of the corresponding upper magnetic domain D_U, by the antiferromagnetic coupling between the corresponding upper magnetic domain D_U and the corresponding lower magnetic domain D_L.

In some embodiments, each of the lower magnetic layer 110, the upper magnetic layer 130 and the magnetic pattern 154 may include at least one of cobalt (Co), iron (Fe), or nickel (Ni) and may further include at least one of non-magnetic materials such as boron (B), zinc (Zn), aluminum (Al), titanium (Ti), ruthenium (Ru), tantalum (Ta), silicon (Si), silver (Ag), gold (Au), copper (Cu), carbon (C), and nitrogen (N). For example, each of the lower magnetic layer 110, the upper magnetic layer 130 and the magnetic pattern 154 may include at least one of a perpendicular magnetic material (e.g., CoFeTb, CoFeGd, or CoFeDy), a perpendicular magnetic material having a L1₀ structure, a CoPt alloy having a hexagonal close packed (HCP) lattice structure, or a perpendicular magnetic structure. The perpendicular magnetic material having the L1₀ structure may include at least one of FePt having the L1₀ structure, FePd having the L1₀ structure, CoPd having the L1₀ structure, or CoPt having the L1₀ structure. The perpendicular magnetic structure may include magnetic layers and non-magnetic layers, which are alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where ‘n’ denotes the number of bilayers. In certain embodiments, each of the lower magnetic layer 110, the upper magnetic layer 130 and the magnetic pattern 154 may include CoFeB or a Co-based Heusler alloy.

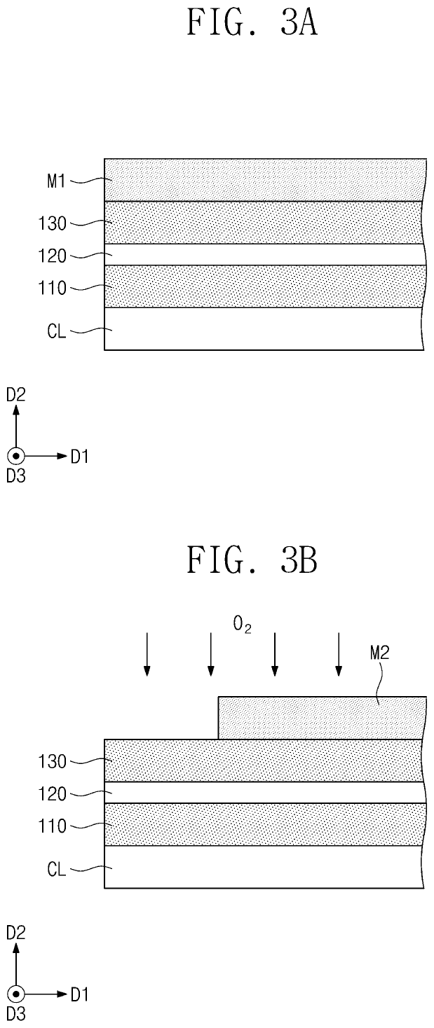

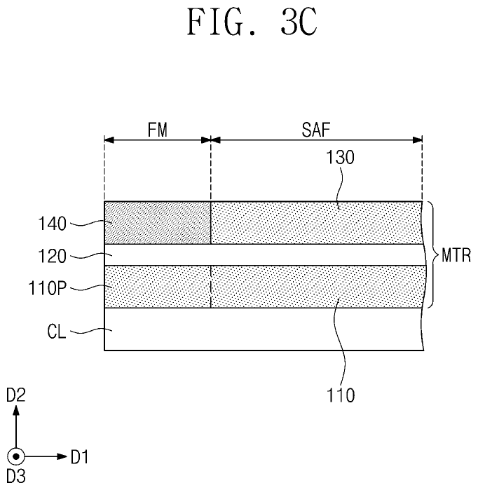

FIGS. 3A to 3C are cross-sectional views corresponding to a portion ‘A’ of FIG. 2 to illustrate a method of manufacturing a magnetic memory device according to some embodiments of the present disclosure. Hereinafter, the descriptions to the same features as mentioned with reference to FIGS. 1 and 2 will be omitted for the purpose of ease and convenience in explanation.

Referring to FIG. 3A, a conductive line CL, a lower magnetic layer 110, a spacer layer 120, and an upper magnetic layer 130 may be formed to extend in the first direction D1. The lower magnetic layer 110, the spacer layer 120, and the upper magnetic layer 130 may be sequentially stacked on the conductive line CL in the second direction D2.

For example, the formation of the conductive line CL, the lower magnetic layer 110, the spacer layer 120 and the upper magnetic layer 130 may include sequentially depositing a conductive layer, a first magnetic layer, a non-magnetic layer and a second magnetic layer, forming a first mask pattern M1 on the second magnetic layer, and sequentially etching the second magnetic layer, the non-magnetic layer, the first magnetic layer and the conductive layer by using the first mask pattern M1 as an etch mask. The conductive layer, the first magnetic layer, the non-magnetic layer, and the second magnetic layer may be formed using a chemical vapor deposition (CVD) method and/or a physical vapor deposition (PVD) method and may be formed using, for example, a sputtering deposition method. The first mask pattern M1 may have a line shape extending in the first direction D1 and may be a photoresist pattern or a hard mask pattern. The second magnetic layer, the non-magnetic layer, the first magnetic layer and the conductive layer may be sequentially etched by, for example, an ion beam etching process. The upper magnetic layer 130, the spacer layer 120, the lower magnetic layer 110, and the conductive line CL may be formed by etching the second magnetic layer, the non-magnetic layer, the first magnetic layer, and the conductive layer, respectively. The lower magnetic layer 110 and the upper magnetic layer 130 may be antiferromagnetically coupled to each other by the spacer layer 120.

After the formation of the conductive line CL, the lower magnetic layer 110, the spacer layer 120 and the upper magnetic layer 130, the first mask pattern M1 may be removed. The first mask pattern M1 may be removed by, for example, an ashing process and/or a strip process.

Referring to FIG. 3B, a second mask pattern M2 may be formed on the upper magnetic layer 130. The second mask pattern M2 may expose a portion of the upper magnetic layer 130 and may at least partially cover a remaining portion of the upper magnetic layer 130. The second mask pattern M2 may be a photoresist pattern or a hard mask pattern. The second mask pattern M2 may include a metal nitride and may include, for example, TaN.

An oxidation process may be performed on the upper magnetic layer 130. The second mask pattern M2 may be used as a mask of the oxidation process. The oxidation process may include, for example, an oxygen plasma treatment.

Referring to FIG. 3C, the portion of the upper magnetic layer 130 which is exposed by the second mask pattern M2 may be oxidized by the oxidation process, and thus a non-magnetic pattern 140 may be formed at a side of the upper magnetic layer 130. The non-magnetic pattern 140 may include a metal oxide. The non-magnetic pattern 140 may include the same magnetic element as the upper magnetic layer 130 and may further include oxygen.

The spacer layer 120 may be used as an oxidation stop layer of the oxidation process. Thus, a portion 110P of the lower magnetic layer 110, which vertically overlaps with the non-magnetic pattern 140 (e.g., in the second direction D2), may not be oxidized by the oxidation process but may maintain a ferromagnetic property.

After the formation of the non-magnetic pattern 140 by the oxidation process, the second mask pattern M2 may be removed. The second mask pattern M2 may be removed by, for example, an ashing process and/or a strip process.

The lower magnetic layer 110, the spacer layer 120, the upper magnetic layer 130, and the non-magnetic pattern 140 may constitute a magnetic track MTR. The conductive line CL and the magnetic track MTR may have line shapes extending in the first direction D1.

The magnetic track MTR may include a synthetic antiferromagnetic region SAF and a ferromagnetic region FM. The synthetic antiferromagnetic region SAF may be a region in which the lower magnetic layer 110 and the upper magnetic layer 130 are antiferromagnetically coupled to each other by the spacer layer 120. The ferromagnetic region FM may include the non-magnetic pattern 140 and the portion 110P of the lower magnetic layer 110 which vertically overlaps with the non-magnetic pattern 140. The magnetic track MTR may have a ferromagnet-synthetic antiferromagnet (FM-SAF) lateral junction structure in which the ferromagnetic region FM and the synthetic antiferromagnetic region SAF are joined to each other in the first direction D1.

Referring again to FIG. 2, a read/write unit 150 may be formed on the synthetic antiferromagnetic region SAF of the magnetic track MTR. For example, the formation of the read/write unit 150 may include sequentially forming a tunnel insulating layer, a magnetic layer and an electrode layer on the magnetic track MTR, and etching the tunnel insulating layer, the magnetic layer and the electrode layer. A tunnel barrier pattern 152, a magnetic pattern 154 and an electrode pattern 156 may be formed by etching the tunnel insulating layer, the magnetic layer and the electrode layer, respectively.

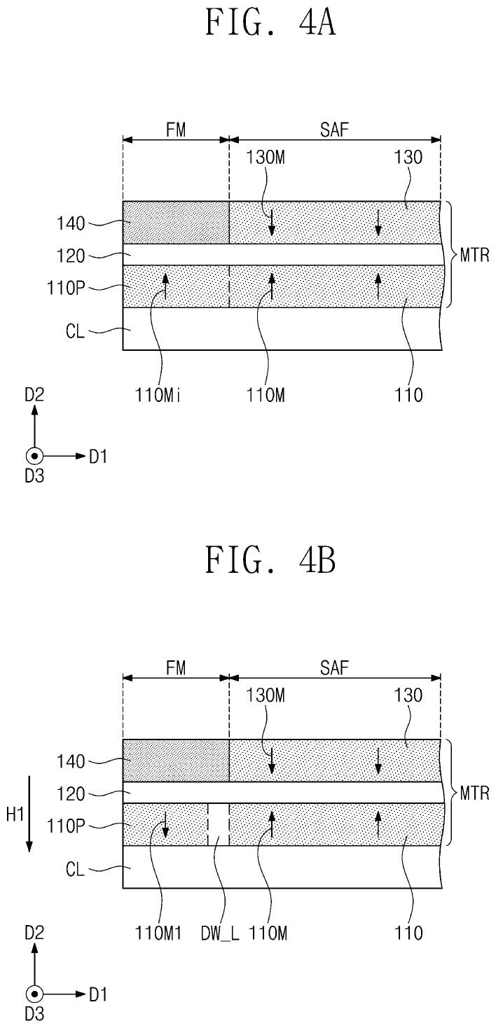

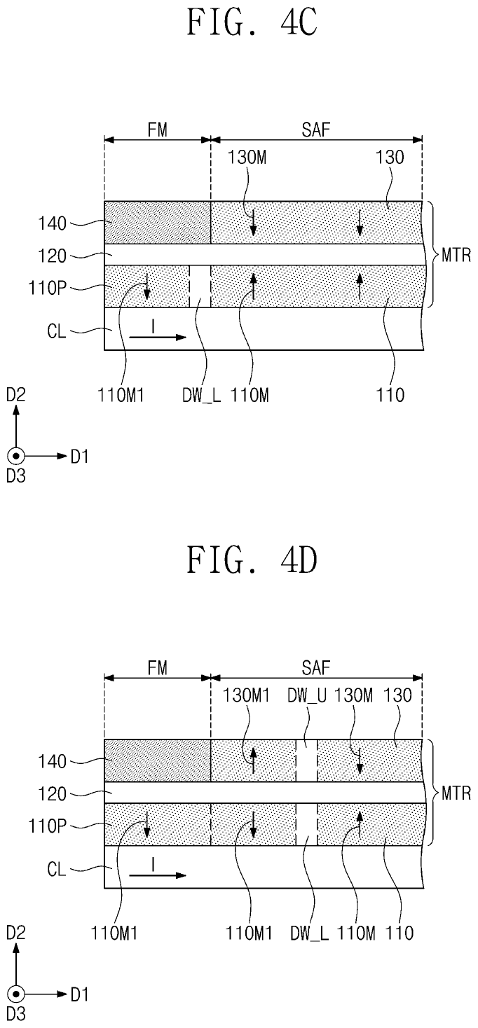

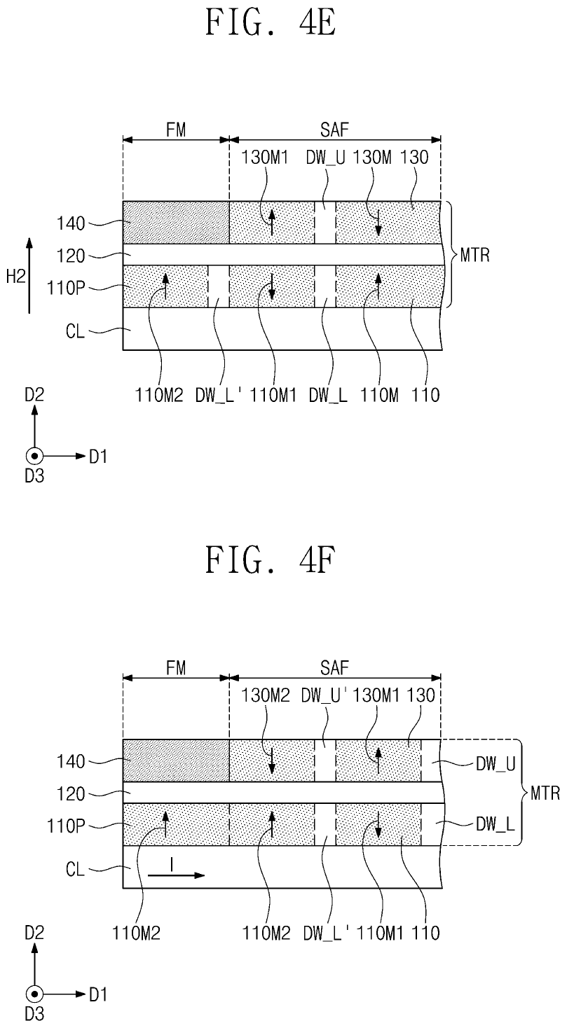

FIGS. 4A to 4F are cross-sectional views corresponding to the portion ‘A’ of FIG. 2 to illustrate a method for initializing a magnetic memory device according to some embodiments of the present disclosure. Hereinafter, the descriptions to the same features as mentioned with reference to FIGS. 1 and 2 will be omitted for the purpose of ease and convenience in explanation.

Referring to FIG. 4A, a magnetic memory device may include a conductive line CL and a magnetic track MTR on the conductive line CL. The magnetic track MTR may include a lower magnetic layer 110, a spacer layer 120, and an upper magnetic layer 130 which are sequentially stacked on the conductive line CL, and may further include a non-magnetic pattern 140 on the spacer layer 120 and adjacent a side of the upper magnetic layer 130. The non-magnetic pattern 140 may vertically overlap with a portion 110P of the lower magnetic layer 110 in the second direction D2. The magnetic track MTR may include a synthetic antiferromagnetic region SAF in which the lower magnetic layer 110 and the upper magnetic layer 130 are antiferromagnetically coupled to each other by the spacer layer 120, and a ferromagnetic region FM including the non-magnetic pattern 140 and the portion 110P of the lower magnetic layer 110 which vertically overlap with each other (e.g., in the second direction D2).

In some embodiments, the lower magnetic layer 110 may have a magnetization direction 110M substantially perpendicular to an interface between the lower magnetic layer 110 and the spacer layer 120, and the upper magnetic layer 130 may have a magnetization direction 130M substantially perpendicular to an interface between the upper magnetic layer 130 and the spacer layer 120. The lower magnetic layer 110 and the upper magnetic layer 130 may be antiferromagnetically coupled to each other by the spacer layer 120, and thus the magnetization direction 130M of the upper magnetic layer 130 may be antiparallel to the magnetization direction 110M of the lower magnetic layer 110. For example, the magnetization direction 110M of the lower magnetic layer 110 may be aligned in an up-direction, and the magnetization direction 130M of the upper magnetic layer 130 may be aligned in a down-direction.

An initial magnetization direction 110Mi of the portion 110P of the lower magnetic layer 110 which vertically overlaps with the non-magnetic pattern 140 may be the same as the magnetization direction 110M of the lower magnetic layer 110. For example, the initial magnetization direction 110Mi of the portion 110P of the lower magnetic layer 110 may be aligned in the up-direction.

Referring to FIG. 4B, a first external magnetic field H1 may be applied to the magnetic track MTR. A direction of the first external magnetic field H1 may be an opposite direction to the initial magnetization direction 110Mi of the portion 110P of the lower magnetic layer 110. For example. the direction of the first external magnetic field H1 may be the down-direction.

A coercivity (Hc) of the synthetic antiferromagnetic region SAF of the magnetic track MTR may be greater than a coercivity (Hc) of the ferromagnetic region FM of the magnetic track MTR. Since the synthetic antiferromagnetic region SAF of the magnetic track MTR has the relatively great coercivity (Hc), the magnetization directions 110M and 130M of the lower magnetic layer 110 and the upper magnetic layer 130 in the synthetic antiferromagnetic region SAF of the magnetic track MTR may not be reversed by the first external magnetic field H1. Since the ferromagnetic region FM of the magnetic track MTR has the relatively small coercivity (Hc), the initial magnetization direction 110Mi of the portion 110P of the lower magnetic layer 110 in the ferromagnetic region FM of the magnetic track MTR may be reversed by the first external magnetic field H1. Thus, the portion 110P of the lower magnetic layer 110 may have a first magnetization direction 110M1 aligned in the down-direction.

Since the initial magnetization direction 110Mi of the portion 110P of the lower magnetic layer 110 is reversed to the first magnetization direction 110M1 by the first external magnetic field H1, a lower magnetic domain wall DW_L may be formed in the portion 110P of the lower magnetic layer 110, which is adjacent to a junction between the ferromagnetic region FM and the synthetic antiferromagnetic region SAF.

Referring to FIG. 4C, a current I may be applied to flow in the conductive line CL in the first direction D1 (or the opposite direction to the first direction D1). Thus, the lower magnetic domain wall DW_L formed in the portion 110P of the lower magnetic layer 110 in the ferromagnetic region FM may be injected into the lower magnetic layer 110 in the synthetic antiferromagnetic region SAF. For example, the lower magnetic domain wall DW_L may move in the first direction D1.

Referring to FIG. 4D, by the current I applied to the conductive line CL, the lower magnetic domain wall DW_L may be injected into the lower magnetic layer 110 in the synthetic antiferromagnetic region SAF and may move in the lower magnetic layer 110 in the synthetic antiferromagnetic region SAF in the first direction D1. With the movement of the lower magnetic domain wall DW_L, the magnetization direction 110M of the lower magnetic layer 110 may be reversed to the first magnetization direction 110M1 aligned in the down-direction.

By the antiferromagnetic coupling between the upper magnetic layer 130 and the lower magnetic layer 110, the magnetization direction 130M of the upper magnetic layer 130 may be reversed to be antiferromagnetically coupled to the first magnetization direction 110M1 of the lower magnetic layer 110. A reversed magnetization direction 130M1 of the upper magnetic layer 130 may be antiferromagnetically coupled to the first magnetization direction 110M1 of the lower magnetic layer 110 and may be aligned in, for example, the up-direction. Since the upper magnetic layer 130 has the reversed magnetization direction 130M1, an upper magnetic domain wall DW U may be formed in the upper magnetic layer 130. The upper magnetic domain wall DW U may vertically overlap with the lower magnetic domain wall DW_L (e.g., in the second direction D2).

Referring to FIG. 4E, a second external magnetic field H2 may be applied to the magnetic track MTR. A direction of the second external magnetic field H2 may be an opposite direction to the first magnetization direction 110M1 of the portion 110P of the lower magnetic layer 110. For example, the direction of the second external magnetic field H2 may be the up-direction.

Since the synthetic antiferromagnetic region SAF of the magnetic track MTR has the relatively great coercivity (Hc), the magnetization directions 110M, 110M1, 130M and 130M1 of the lower magnetic layer 110 and the upper magnetic layer 130 in the synthetic antiferromagnetic region SAF of the magnetic track MTR may not be reversed by the second external magnetic field H2. Since the ferromagnetic region FM of the magnetic track MTR has the relatively small coercivity (Hc), the first magnetization direction 110M1 of the portion 110P of the lower magnetic layer 110 in the ferromagnetic region FM of the magnetic track MTR may be reversed by the second external magnetic field H2. Thus, the portion 110P of the lower magnetic layer 110 may have a second magnetization direction 110M2 aligned in the up-direction.

Since the first magnetization direction 110M1 of the portion 110P of the lower magnetic layer 110 is reversed to the second magnetization direction 110M2 by the second external magnetic field H2, an additional lower magnetic domain wall DW_L′ may be formed in the portion 110P of the lower magnetic layer 110 which is adjacent to the junction between the ferromagnetic region FM and the synthetic antiferromagnetic region SAF.

Referring to FIG. 4F, a current I may be applied to flow in the conductive line CL in the first direction D1 (or the opposite direction to the first direction D1). By the current I applied to the conductive line CL, the additional lower magnetic domain wall DW_L′ may be injected into the lower magnetic layer 110 in the synthetic antiferromagnetic region SAF, and the lower magnetic domain walls DW_L′ and DW_L may move in the lower magnetic layer 110 in the synthetic antiferromagnetic region SAF in the first direction D1.

The magnetization directions 110M and 110M1 of the lower magnetic layer 110 may be reversed with the movement of the lower magnetic domain walls DW_L′ and DW_L. For example, with the movement of the lower magnetic domain wall DW_L, the magnetization direction 110M of the lower magnetic layer 110 may be reversed to the first magnetization direction 110M1 aligned in the down-direction. In addition, with the movement of the additional lower magnetic domain wall DW_L′, the first magnetization direction 110M1 of the lower magnetic layer 110 may be reversed to the second magnetization direction 110M2 aligned in the up-direction.

By the antiferromagnetic coupling between the upper magnetic layer 130 and the lower magnetic layer 110, the magnetization directions 130M and 130M1 of the upper magnetic layer 130 may be reversed to be antiferromagnetically coupled to the reversed magnetization directions 110M1 and 110M2 of the lower magnetic layer 110. For example, a reversed magnetization direction 130M1 of the upper magnetic layer 130 may be antiferromagnetically coupled to the first magnetization direction 110M1 of the lower magnetic layer 110 and may be aligned in the up-direction. In addition, a re-reversed magnetization direction 130M2 of the upper magnetic layer 130 may be antiferromagnetically coupled to the second magnetization direction 110M2 of the lower magnetic layer 110 and may be aligned in the down-direction.

Since the upper magnetic layer 130 has the reversed magnetization directions 130M1 and 130M2, an additional upper magnetic domain wall DW_U′ may be formed in the upper magnetic layer 130. The upper magnetic domain walls DW_U′ and DW_U may vertically overlap with the lower magnetic domain walls DW_L′ and DW_L (e.g., in the second direction D2), respectively.

By applying an external magnetic field (e.g., the first and second external magnetic fields H1 and H2) to the magnetic track MTR, the lower magnetic domain wall DW_L may be formed in the portion 110P of the lower magnetic layer 110 in the ferromagnetic region FM of the magnetic track MTR. By applying a current to the conductive line CL, the lower magnetic domain wall DW_L formed in the portion 110P of the lower magnetic layer 110 may be injected into the lower magnetic layer 110 in the synthetic antiferromagnetic region SAF of the magnetic track MTR. The magnetic track MTR may be initialized by repeatedly performing the formation and injection of the lower magnetic domain wall DW_L as described with reference to FIGS. 4A to 4F. The lower magnetic layer 110 of the initialized magnetic track MTR may include the lower magnetic domains D_L arranged in the first direction D1 and the lower magnetic domain walls DW_L therebetween as described with reference to FIG. 2, and the upper magnetic layer 130 of the initialized magnetic track MTR may include the upper magnetic domains D_U arranged in the first direction D1 and the upper magnetic domain walls DW_U therebetween as described with reference to FIG. 2.

According to the present disclosure, the magnetic track MTR may include the lower magnetic layer 110, the upper magnetic layer 130, the spacer layer 120 between the lower magnetic layer 110 and the upper magnetic layer 130, and the non-magnetic pattern 140 on the spacer layer 120 and adjacent a side of the upper magnetic layer 130. The non-magnetic pattern 140 may vertically overlap with a portion of the lower magnetic layer 110 in the second direction D2. The magnetic track MTR may include the synthetic antiferromagnetic region SAF in which the lower magnetic layer 110 and the upper magnetic layer 130 are antiferromagnetically coupled to each other by the spacer layer 120, and the ferromagnetic region FM including the non-magnetic pattern 140 and the portion of the lower magnetic layer 110 which vertically overlap with each other (e.g., in the second direction D2). The magnetic track MTR may have a ferromagnet-synthetic antiferromagnet (FM-SAF) lateral junction structure in which the ferromagnetic region FM and the synthetic antiferromagnetic region SAF are joined to each other in the first direction D1. In this case, by applying the external magnetic field to the magnetic track MTR, the lower magnetic domain wall DW_L may be easily formed in the portion of the lower magnetic layer 110 in the ferromagnetic region FM of the magnetic track MTR. In addition, by applying the current to the conductive line CL under the magnetic track MTR, the lower magnetic domain wall DW_L formed in the portion 110P of the lower magnetic layer 110 may be easily injected into the lower magnetic layer 110 in the synthetic antiferromagnetic region SAF of the magnetic track MTR.

As a result, it is possible to provide the magnetic memory device capable of easily injecting a magnetic domain wall into the magnetic track MTR including the synthetic antiferromagnetic structure, and it is possible to provide the method for initializing the magnetic memory device, which is capable of easily injecting the magnetic domain wall into the magnetic track MTR.

In some embodiments, a plurality of magnetic tracks MTR spaced apart from each other may be provided. As described above, each of the plurality of magnetic tracks MTR may have the ferromagnet-synthetic antiferromagnet (FM-SAF) lateral junction structure in which the ferromagnetic region FM and the synthetic antiferromagnetic region SAF are joined to each other in the first direction D1. In this case, by applying an external magnetic field to the plurality of magnetic tracks MTR, a lower magnetic domain wall DW_L may be easily formed in the portion of the lower magnetic layer 110 in the ferromagnetic region FM of each of the plurality of magnetic tracks MTR. In addition, by applying a current to the conductive line CL under each of the plurality of magnetic tracks MTR, the lower magnetic domain wall DW_L formed in the portion 110P of the lower magnetic layer 110 may be easily injected into the lower magnetic layer 110 in the synthetic antiferromagnetic region SAF of the magnetic track MTR. Thus, it is possible to provide a magnetic memory device and a method for initializing the same, which are capable of easily injecting magnetic domain walls into the plurality of magnetic tracks MTR including the synthetic antiferromagnetic structures.

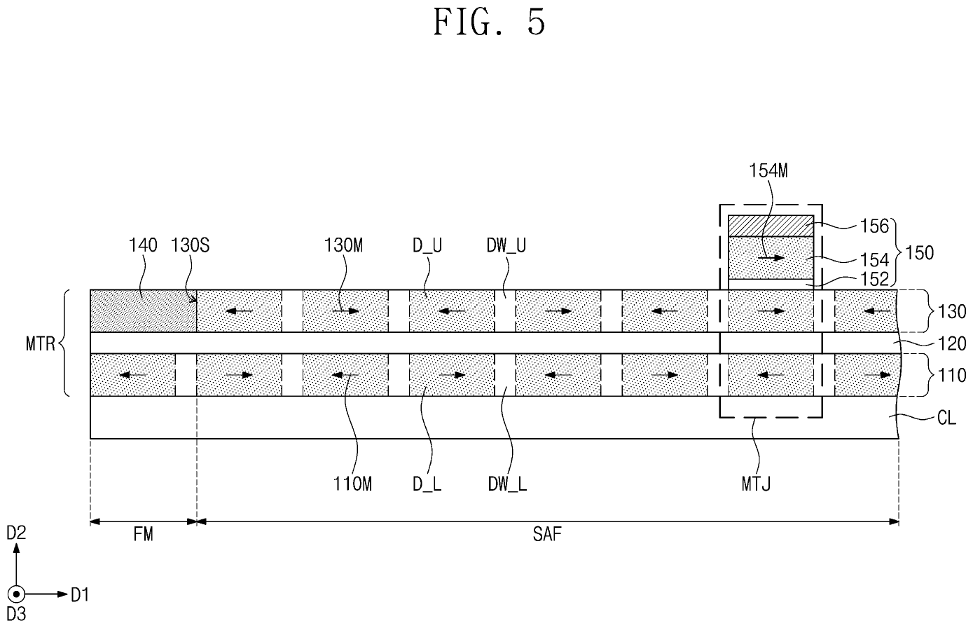

FIG. 5 is a cross-sectional view illustrating a magnetic memory device according to some embodiments of the present disclosure. Hereinafter, differences between the present embodiments and the above embodiments of FIGS. 1 and 2 will be mainly described for the purpose of ease and convenience in explanation.

Referring to FIG. 5, the lower magnetic domains D_L in the lower magnetic layer 110 and the upper magnetic domains D_U in the upper magnetic layer 130 may have in-plane magnetic anisotropy (IMA). Each of the lower magnetic domains D_L in the lower magnetic layer 110 may have a magnetization direction 110M parallel to an interface between the lower magnetic layer 110 and the spacer layer 120, and magnetization directions 110M of lower magnetic domains D_L adjacent directly to each other may be opposite to each other. Each of the lower magnetic domain walls DW_L may define a boundary between the adjacent lower magnetic domains D_L having the magnetization directions 110M opposite to each other. Each of the upper magnetic domains D_U in the upper magnetic layer 130 may have a magnetization direction 130M parallel to an interface between the upper magnetic layer 130 and the spacer layer 120, and magnetization directions 130M of upper magnetic domains D_U adjacent directly to each other may be opposite to each other. Each of the upper magnetic domain walls DW U may define a boundary between the adjacent upper magnetic domains D_U having the magnetization directions 130M opposite to each other.

The magnetic pattern 154 of the read/write unit 150 may have in-plane magnetic anisotropy (IMA). The magnetic pattern 154 may have a magnetization direction 154M parallel to an interface between the magnetic pattern 154 and the tunnel barrier pattern 152, and the magnetization direction 154M of the magnetic pattern 154 may be fixed in one direction. The magnetization directions 130M of the upper magnetic domains D_U in the upper magnetic layer 130 and the magnetization directions 110M of the lower magnetic domains D_L in the lower magnetic layer 110 may be changeable to be parallel or antiparallel to the magnetization direction 154M of the magnetic pattern 154.

In some embodiments, each of the lower magnetic layer 110, the upper magnetic layer 130, and the magnetic pattern 154 may include a ferromagnetic material, and the magnetic pattern 154 may further include an antiferromagnetic material for pinning or fixing a magnetization direction of the ferromagnetic material.

Except for the aforementioned differences, other features and components of the magnetic memory device according to the present embodiments may be substantially the same as corresponding features and components of the magnetic memory device described with reference to FIGS. 1 and 2. In addition, the magnetic memory device according to the present embodiments may be formed by substantially the same method as described with reference to FIGS. 3A to 3C and may be initialized by substantially the same method as described with reference to FIGS. 4A to 4F.

According to the present disclosure, the magnetic track may have the ferromagnet-synthetic antiferromagnet (FM-SAF) lateral junction structure in which the ferromagnetic region and the synthetic antiferromagnetic region are joined to each other in the first direction. In this case, by applying an external magnetic field to the magnetic track, a magnetic domain wall may be easily formed in the ferromagnetic region of the magnetic track. In addition, by applying a current to the conductive line under the magnetic track, the magnetic domain wall formed in the ferromagnetic region may be easily injected into the synthetic antiferromagnetic region of the magnetic track.

As a result, it is possible to provide the magnetic memory device capable of easily injecting the magnetic domain wall into the magnetic track including the synthetic antiferromagnetic structure, and it is possible to provide the method for initializing the magnetic memory device, which is capable of easily injecting the magnetic domain wall into the magnetic track.

While example embodiments of the present disclosure have been particularly shown and described, it will be understood by one of ordinary skill in the art that variations in form and detail may be made therein without departing from the spirit and scope of the attached claims.

1. A magnetic memory device comprising:
a conductive line extending in a first direction; and
a magnetic track extending in the first direction on the conductive line,
wherein the magnetic track comprises:
a lower magnetic layer, a spacer layer, and an upper magnetic layer sequentially stacked on the conductive line; and
a non-magnetic pattern on the spacer layer and adjacent a side of the upper magnetic layer,
wherein the non-magnetic pattern vertically overlaps, in a second direction substantially perpendicular to the first direction, with a portion of the lower magnetic layer, and
wherein the lower magnetic layer and the upper magnetic layer are antiferromagnetically coupled to each other by the spacer layer.

2. The magnetic memory device of claim 1, wherein the non-magnetic pattern comprises a same magnetic element as a magnetic element in the upper magnetic layer.

3. The magnetic memory device of claim 2, wherein the non-magnetic pattern further comprises oxygen.

4. The magnetic memory device of claim 1, wherein the conductive line comprises a heavy metal having an atomic number of thirty (30) or more, and is configured to generate spin-orbit torque by a current flowing therein.

5. The magnetic memory device of claim 1, wherein the lower magnetic layer is between the conductive line and the spacer layer, and wherein the spacer layer is between the lower magnetic layer and the upper magnetic layer and extends between the non-magnetic pattern and the portion of the lower magnetic layer which vertically overlaps with the non-magnetic pattern.

6. The magnetic memory device of claim 1, wherein the lower magnetic layer comprises a plurality of lower magnetic domains arranged in the first direction and a plurality of lower magnetic domain walls, wherein the plurality of lower magnetic domains and the plurality of lower magnetic domain walls are alternately arranged in the first direction,
wherein the upper magnetic layer comprises a plurality of upper magnetic domains arranged in the first direction and a plurality of upper magnetic domain walls, wherein the plurality of upper magnetic domains and the plurality of upper magnetic domain walls are alternately arranged in the first direction, and
wherein each of the plurality of upper magnetic domains vertically overlap with a respective one of the plurality of lower magnetic domains.

7. The magnetic memory device of claim 6,
wherein each of the lower magnetic domains in the lower magnetic layer has a magnetization direction substantially perpendicular to an interface between the lower magnetic layer and the spacer layer, and ones of the lower magnetic domains directly adjacent to each other have magnetization directions opposite to each other, with each of the lower magnetic domain walls defining a boundary between the ones of the lower magnetic domains having opposite magnetization directions; and
wherein each of the upper magnetic domains in the upper magnetic layer has a magnetization direction substantially perpendicular to an interface between the upper magnetic layer and the spacer layer, and ones of the upper magnetic domains directly adjacent to each other have magnetization directions opposite to each other, with each of the upper magnetic domain walls defining a boundary between the ones of the upper magnetic domains having opposite magnetization directions.

8. The magnetic memory device of claim 6, wherein the non-magnetic pattern vertically overlaps one of the plurality of lower magnetic domains.

9. The magnetic memory device of claim 1, wherein the non-magnetic pattern comprises a metal oxide.

10. The magnetic memory device of claim 1,
wherein the magnetic track has a ferromagnet-synthetic antiferromagnet (FM-SAF) lateral junction structure in which a ferromagnetic region and a synthetic antiferromagnetic region are joined to each other in the first direction,
wherein the synthetic antiferromagnetic region is a region in which the lower magnetic layer and the upper magnetic layer are antiferromagnetically coupled to each other by the spacer layer, and
wherein the ferromagnetic region comprises the non-magnetic pattern and the portion of the lower magnetic layer which vertically overlaps with the non-magnetic pattern.

11. The magnetic memory device of claim 6, further comprising:
a read/write unit on a synthetic antiferromagnetic region of the magnetic track,
wherein the read/write unit vertically overlaps with one of the plurality of upper magnetic domains and a corresponding one of the plurality of lower magnetic domains.

12. The magnetic memory device of claim 11, wherein the magnetic track is between the conductive line and the read/write unit.

13. A magnetic memory device comprising:
a magnetic track extending in a first direction,
wherein the magnetic track comprises:
a lower magnetic layer extending in the first direction;
an upper magnetic layer extending in the first direction on the lower magnetic layer;
a non-magnetic pattern on the lower magnetic layer and adjacent a side of the upper magnetic layer; and
a spacer layer extending in the first direction between the lower magnetic layer and the upper magnetic layer,
wherein the non-magnetic pattern vertically overlaps with a portion of the lower magnetic layer in a second direction substantially perpendicular to the first direction,
wherein the spacer layer extends between the non-magnetic pattern and the portion of the lower magnetic layer which vertically overlaps with the non-magnetic pattern, and
wherein the lower magnetic layer and the upper magnetic layer are antiferromagnetically coupled to each other by the spacer layer.

14. The magnetic memory device of claim 13, wherein the lower magnetic layer comprises lower magnetic domains and lower magnetic domain walls which are alternately arranged in the first direction, and wherein each of the lower magnetic domains has a magnetization direction substantially parallel to an interface between the lower magnetic layer and the spacer layer, and ones of the lower magnetic domains directly adjacent to each other have magnetization directions opposite to each other, with each of the lower magnetic domain walls defining a boundary between the ones of the lower magnetic domains having opposite magnetization directions;
wherein the upper magnetic layer comprises upper magnetic domains and upper magnetic domain walls which are alternately arranged in the first direction, and wherein each of the upper magnetic domains in the upper magnetic layer have a magnetization direction substantially parallel to an interface between the upper magnetic layer and the spacer layer, and ones of the upper magnetic domains directly adjacent to each other have magnetization directions opposite to each other, with each of the upper magnetic domain walls defining a boundary between the ones of the upper magnetic domains having opposite magnetization directions, and
wherein each of the upper magnetic domains vertically overlap with a respective one of the lower magnetic domains in the second direction.

15. The magnetic memory device of claim 14, wherein the non-magnetic pattern vertically overlaps one of the lower magnetic domains in the second direction.

16. The magnetic memory device of claim 13, wherein the non-magnetic pattern comprises oxygen.

17. The magnetic memory device of claim 13, wherein the non-magnetic pattern comprises a metal oxide.

18. The magnetic memory device of claim 13, wherein the non-magnetic pattern comprises a same magnetic element as a magnetic element in the upper magnetic layer and further comprises oxygen.

19. The magnetic memory device of claim 13, further comprising:
a conductive line under the magnetic track and extending in the first direction,
wherein the lower magnetic layer is between the conductive line and the spacer layer, and
wherein the conductive line comprises a heavy metal element.

20. The magnetic memory device of claim 13, wherein the non-magnetic pattern is in contact with a side surface of the upper magnetic layer.

21.-26. (canceled)
